(19) United States
(12) Patent Application Publication
(10) Pub. No.: US 2012/0262889 A1
(43) Pub. Date: Oct. 18, 2012

(54) ELECTROMAGNETIC SHIELDING COVER

(75) Inventor: CHANG-WEI TSAO, Tu-Cheng, New Taipei (TW)

(73) Assignee: CHI MEI COMMUNICATION SYSTEMS, INC., Tu-Cheng (TW)

(21) Appl. No.: 13/197,259

(22) Filed: Aug. 3, 2011

(30) Foreign Application Priority Data
Apr. 18, 2011 (TW) 100206808

(51) Int. Cl. H05K 5/03

(52) U.S. Cl. 361/752

(57) ABSTRACT

An electromagnetic shielding cover is configured to shield different kinds of electronic assemblies on a PCB. The PCB includes at least one shielding frame. The at least one shielding frame surrounds the electronic assemblies. The electromagnetic shielding cover comprises a film and an electrically-conductive layer coated on the film. The film is made of insulated materials. The electrically-conductive layer has at least one electrically-conductive area corresponding to the at least one shielding frame, each electrically-conductive area defines a sealed shielding space in combination with a corresponding shielding frame, to shield the electronic assemblies.

### BACKGROUND

1. Technical Field

The present disclosure relates to housing assemblies for an electronic device, and particularly to an electromagnetic shielding cover for an electronic device.

2. Description of Related Art

The operation of portable electronic devices such as mobile telephones, televisions, radios, computers, medical instruments, business machines, communication equipments, and the like generates electromagnetic radiation within the electronic circuitry/assemblies of the equipment, and is termed “electromagnetic interference” or “EMI”. EMI is known to interfere with the operation of other nearby electronic devices.

To attenuate EMI effects, shielding covers having the capability of absorbing and/or reflecting EMI energy may be employed to confine the EMI energy within a source assembly, and to insulate that assembly or other “target” devices from other source assemblies. One type of shielding cover may be made of metal, which is expensive. Another type of shielding cover may comprise a plastic substrate and an electrically-conductive layer coated on the plastic substrate. However, when there are many source assemblies to shield from each other, it is expensive to set a shielding cover for each source assembly, and it also takes time to mount the shielding covers.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary electromagnetic shielding cover. Moreover, in the drawings like reference numerals designate corresponding parts throughout the several views. Wherever possible, the same reference numbers are used throughout the drawings to refer to the same or like elements of an exemplary embodiment.

FIG. 1 is a schematic view of one embodiment of an electromagnetic shielding cover disengaged from a PCB.

FIG. 2 is an assembled, schematic view of the electromagnetic shielding cover mounted on the PCB of FIG. 1.

FIG. 3 is an enlarged cross-sectional view taken along line III-III of FIG. 2.

FIG. 4 is an enlarged view of a circled portion IV of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

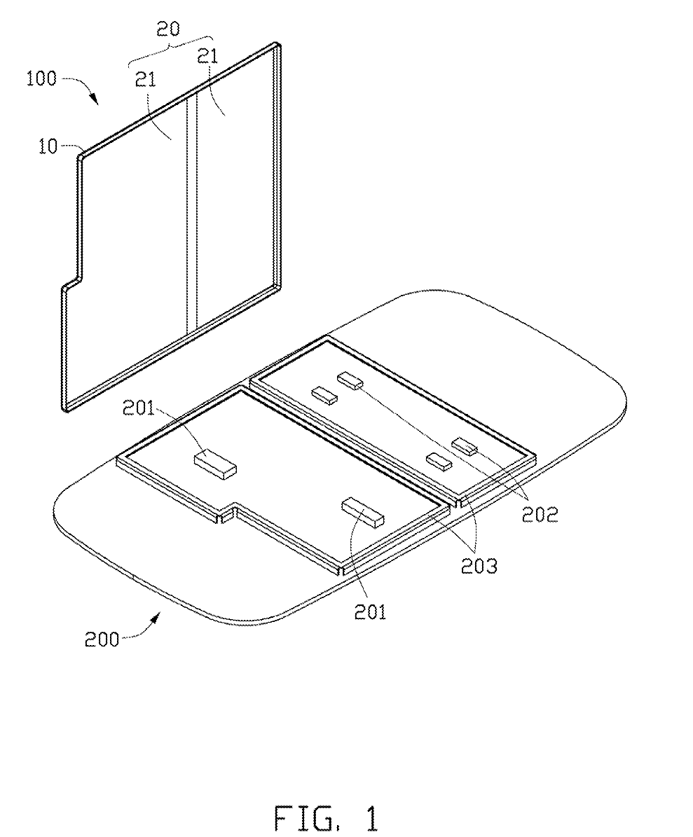

FIG. 1 is a schematic view of one embodiment of an electromagnetic shielding cover 100 disengaged from a printed circuit board (PCB) 200. The electromagnetic shielding cover 100 is configured to shield a plurality of electronic assemblies in an electronic device, to insulate each electronic assembly from EMI of the other electronic assemblies in the electronic device, or from EMI of other electronic assemblies outside of the electronic device. In this exemplary embodiment, the electromagnetic shielding cover 100 is mounted on the PCB 200, to shield different kinds of electronic assemblies, such as a plurality of first electronic assemblies 201 and a plurality of second electronic assemblies 202. The first electronic assemblies 201 have little EMI effects on each other, and so can be shielded together by one shielding cover. The second electronic assemblies 202 have little EMI effects on each other, and can be shielded together by another shielding cover.

The PCB 200 is a soft circuit board, and includes two shielding frames 203 mounted on the PCB 200, which are configured to fix the cover 100 on the PCB 200. The frames 203 are separably positioned, and one of the frames 203 surrounds the first electronic assemblies 201, the other frame 203 surrounds the second electronic assemblies 202. The frames 203 are made of metal in this embodiment.

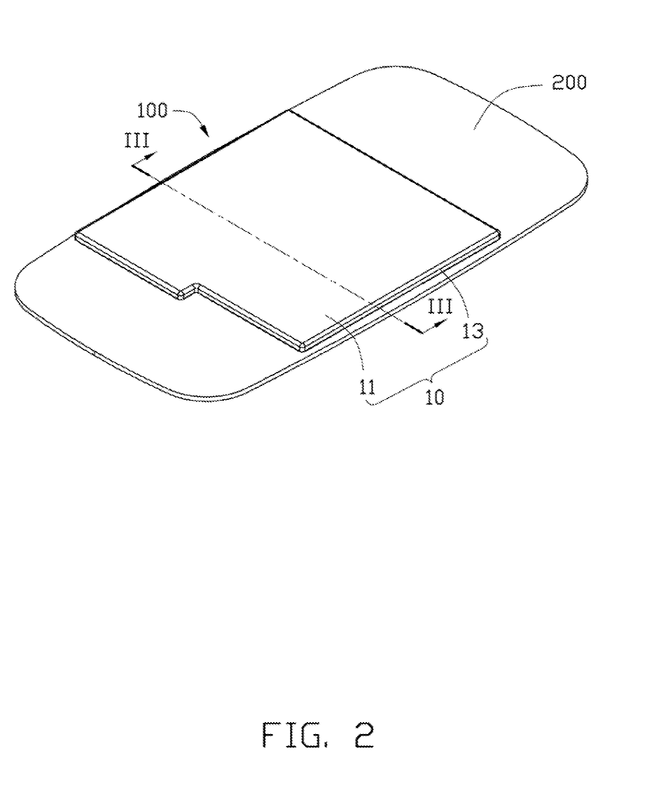

Also referring to FIG. 2, the cover 100 is mounted on the frames 203, and covers the PCB 200, to prevent EMI of either of the first electronic assemblies 201 or the second electronic assemblies 202 affecting the other, and shielding the electronic assemblies 201, 202 in the cover 100 from EMI caused by other electronic assemblies outside of the electronic device. The cover 100 includes a film 10 and an electrically-conductive layer 20 coated on the film 10. The film 10 is made of insulative materials, such as polyester film. In this exemplary embodiment, the film 10 is formed using an In-Mold Decoration (IMD) method, and is about 0.2 mm thick. The layer 20 is configured to work in combination with the frames 203 to shield the electronic assemblies 201, 202 in the electronic device. In this exemplary embodiment, the layer 20 has two electrically-conductive areas 21 corresponding to the two frames 203. And the two areas 21 are separated from each other, and each is configured to shield one of the electronic assemblies from EMI by the other electronic assembly.

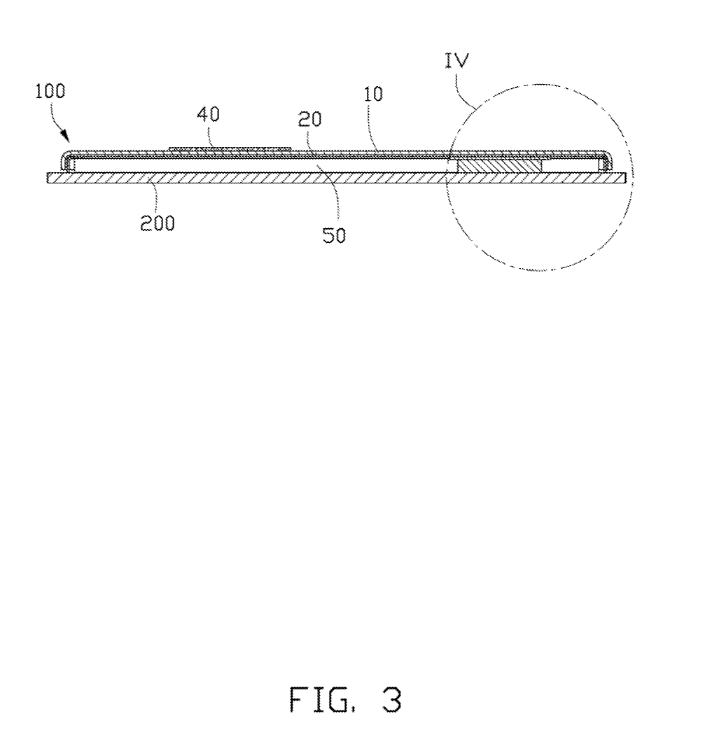

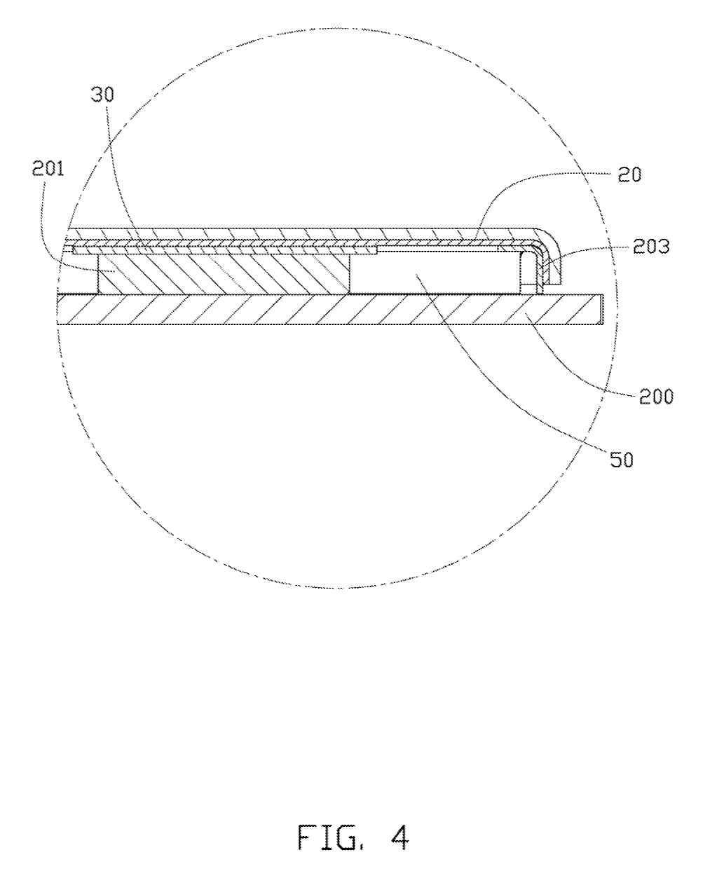

Also referring to FIG. 3 and FIG. 4, in this exemplary embodiment, the film 10 has a top board 11 and an edge 13 formed using In Molding Label (IML) technology. The edge 13 surrounds the board 11. Therefore, the board 11 can cover and stick to the two frames 203, and the edge 13 surrounds the two frames 203. Each area 21 in combination with a corresponding frame 203 defines a sealed shielding space 50. One of the sealed shielding spaces 50 shields the first electronic assemblies 201, and the other sealed shielding space 50 shields the second electronic assemblies 202.

The cover 100 further includes a plurality of insulated portions 30. Each of the insulated portions 30 is an insulated lacquer layer partially coated on the layer 20. The insulated portion 30 is positioned corresponding to the electronic assemblies under the cover 100, and prevent short-circuit contact between the electronic assemblies and the layer 20. It is to be understood that the size of each insulated portion 30 corresponds to the size of the electronic assemblies which the insulated portion 30 covers.

The cover 100 further includes a decorative coating 40. The coating 40 is positioned on the surface of the film 10 far away from the layer 20, and can be decoratively patterned and colored, and may have words and numbers printed thereon.

It is to be understood that the film 10 can just be molded into the top board 11, and the edge 13 is omitted. The top board 11 is large enough to cover the two frames 203, thereafter each area 21 can define the above-mentioned sealed shielding space 50 in combination with the corresponding frame 203.

Obviously, the cover 100 of this exemplary embodiment, which includes an electrically-conductive layer 20 coated on a film 10, rather than typical metal shielding, has a lower cost. Furthermore, the cover 100 is very thin, and occupies less space in electronic device. In addition, the electrically-conductive layer 20 has different electrically-conductive areas 21. Each electrically-conductive area 21 defines a sealed shielding space 50 in combination with the frame 203, to shield different kinds of electronic assemblies (the electronic assemblies 201, 202) in the corresponding shielding space 50. Therefore, the cover 100 can shield a plurality of electronic assemblies from each other, eliminating the need to fabricate and install a separate electromagnetic shielding cover for each electronic assembly, which lowers cost and simplifies assembly.

Although one embodiment of the present disclosure has been specifically described, the present disclosure is not to be construed as being limited thereto. Various changes or modifications may be made to the present disclosure without departing from the scope and spirit of the present disclosure.

What is claimed is:

1. An electromagnetic shielding cover, configured to shield different kinds of electronic assemblies on a PCB, the PCB including at least one shielding frame, the at least one shielding frame surrounding the electronic assemblies, the electromagnetic shielding cover comprising:
a film made of insulative materials; and
an electrically-conductive layer coated on the film, the electrically-conductive layer having at least one electrically-conductive area corresponding to the at least one shielding frame, each electrically-conductive area defining a sealed shielding space in combination with a corresponding shielding frame, to shield the electronic assemblies.

2. The electromagnetic shielding cover of claim 1, wherein the film is formed using an In-Mold Decoration (IMD) method.

3. The electromagnetic shielding cover of claim 1, further comprising a decorative coating positioned on the film far away from the electrically-conductive layer.

4. The electromagnetic shielding cover of claim 1, wherein the shielding frame is made of metal.

5. The electromagnetic shielding cover of claim 1, wherein the film has a top board covers on the shielding frame, the at least one electrically-conductive area is positioned on the top board, thereafter the at least one electrically-conductive area on the top board defines the sealed shielding spaces in combination with the corresponding shielding frame.

6. The electromagnetic shielding cover of claim 5, wherein the top board is formed using In Molding Label (IML) technology.

7. The electromagnetic shielding cover of claim 6, wherein the film further has an edge surrounds the top board, the edge surrounding the shielding frames when the top board covering on the shielding frame.

8. The electromagnetic shielding cover of claim 1, further comprising a plurality of insulated portions positioned on the electrically-conductive layer, and located corresponding to the electronic assembly to prevent short-circuit contact between the electronic assemblies and the electrically-conductive layer.

9. The electromagnetic shielding cover of claim 8, wherein the insulated portion is an insulative lacquer layer.
